(19) United States
(12) Patent Application Publication
(10) Pub. No.: US 2019/0296085 A1
(43) Pub. Date: Sep. 26, 2019

(54) MEMORY DEVICE AND METHOD FOR MANUFACTURING THE SAME

(71) Applicant: TOSHIBA MEMORY CORPORATION, Tokyo (JP)

(72) Inventor: Tetsu MOROOKA, Yokkaichi Mie (JP)

(73) Assignee: TOSHIBA MEMORY CORPORATION, Tokyo (JP)

(21) Appl. No.: 16/124,109

(22) Filed: Sep. 6, 2018

(30) Foreign Application Priority Data
Mar. 22, 2018 (JP) 2018-055379

(51) Int. Cl. H01L 27/24; H01L 45/00; G11C 13/00

(52) U.S. Cl. CPC H01L 27/2481; H01L 45/146; H01L 45/1233; G11C 13/0026; G11C 13/0028; H01L 45/16

(57) ABSTRACT

A memory device includes a first stacked structure including a plurality of first conductive layers extending in a first direction and arrayed along a second direction intersecting with the first direction, a second stacked structure provided on the first stacked structure and including a plurality of second conductive layers extending in the first direction and arrayed along the second direction, an insulating layer provided between the first and second stacked structures, a third conductive layer provided in the first stacked structure and extending in the second direction, and a fourth conductive layer provided in the second stacked structure, extending in the second direction, and including one portion and another portion located more away from the insulating layer in the second direction than the one portion, a length of the one portion in the first direction being larger than a length of the another portion in the first direction.

### CROSS-REFERENCE TO RELATED APPLICATION

This application claims the benefit of and priority to Japanese Patent Application No. 2018-055379, filed Mar. 22, 2018, the entire contents of which are incorporated herein by reference.

### FIELD

Embodiments described herein relate generally to a memory device and a method for manufacturing the same.

### BACKGROUND

As large-capacity nonvolatile memory, two-terminal resistive random access memory, which would become an alternative to existing floating-gate NAND flash memory, is actively being developed. This type of memory enables low-voltage and low-current operation, high-speed switching, and miniaturization and high-density integration of memory cells.

Various materials are being proposed for a variable resistance layer of the resistive random access memory. For example, in a variable resistance layer made from titanium oxide and amorphous silicon, serving as a barrier film, a change in electrical resistance occurs due to modulation of the oxygen vacancy density caused by the application of a bias to titanium oxide.

In a large-capacity memory cell array, a great number of metal wirings called bit lines and word lines are arrayed in an intersecting manner, and a memory cell is formed at an intersection between each bit line and each word line. Write to one memory cell is performed by applying voltages to a bit line BL and a word line WL connected to the memory cell.

### DESCRIPTION OF THE DRAWINGS

FIG. 1 is a block diagram of a memory device according to some embodiments.

FIG. 2 is an equivalent circuit schematic of a memory cell array according to some embodiments.

FIG. 3A, FIG. 3B, and FIG. 3C are schematic views of the memory device according to some embodiments.

FIG. 4A, FIG. 4B, FIG. 4C, FIG. 4D, FIG. 4E, FIG. 4F, FIG. 4G, FIG. 4H, FIG. 4I, FIG. 4J, and FIG. 4K are schematic views illustrating a method for manufacturing the memory device according to some embodiments.

FIG. 5A, FIG. 5B, FIG. 5C, FIG. 5D, FIG. 5E, FIG. 5F, FIG. 5G, FIG. 5H, and FIG. 5I are schematic views illustrating the method for manufacturing the memory device according to some embodiments.

FIG. 6A and FIG. 6B are schematic views of a memory device serving as a comparative configuration for some embodiments.

### DETAILED DESCRIPTION

Embodiments provide a memory device configured to be reduced in contact resistance.

In general, according to some embodiments, a memory device may include a first stacked structure including a plurality of first conductive layers extending in a first direction and arrayed along a second direction intersecting with the first direction and a plurality of first insulating layers extending in the first direction and provided between respective adjacent ones of the plurality of first conductive layers in the second direction, a second stacked structure including a plurality of second conductive layers extending in the first direction and arrayed along the second direction and a plurality of second insulating layers provided between respective adjacent ones of the plurality of second conductive layers in the second direction and extending in the first direction, and provided on the first stacked structure, a third insulating layer provided between the first stacked structure and the second stacked structure, a third conductive layer provided in the first stacked structure, extending in the second direction, connecting the plurality of first conductive layers to the plurality of first insulating layers, and including a first portion and a second portion provided between the first portion and the third insulating layer, a first variable resistance layer provided between each of the plurality of first conductive layers and the plurality of first insulating layers and the third conductive layer in a third direction intersecting with the first direction and the second direction, a fourth conductive layer provided in the second stacked structure, extending in the second direction, connecting the plurality of second conductive layers to the plurality of second insulating layers, and including a third portion and a fourth portion located more away from the third insulating layer in the second direction than the third portion, a length of the third portion in the first direction being larger than a length of the fourth portion in the first direction, a second variable resistance layer provided between each of the plurality of second conductive layers and the plurality of second insulating layers and the fourth conductive layer in the third direction, and a fifth conductive layer provided in the third insulating layer and electrically connecting the third conductive layer to the fourth conductive layer.

Hereinafter, embodiments will be described with reference to the drawings. Furthermore, in the drawings, the same or similar portions are assigned the respective same or similar reference characters.

In the present disclosure, to indicate the positional relationship between, for example, components, an upward direction in the drawings may be referred to as “up” and the downward direction in the drawings may be referred to as “down”. In the present disclosure, the directions referred to as “up” and “down” are not necessarily the direction of gravitational force.

A memory device according to some embodiments may include a first stacked structure including a plurality of first conductive layers extending in a first direction and arrayed along a second direction intersecting with the first direction and a plurality of first insulating layers extending in the first direction and provided between respective adjacent ones of the plurality of first conductive layers in the second direction, a second stacked structure including a plurality of second conductive layers extending in the first direction and arrayed along the second direction and a plurality of second insulating layers provided between respective adjacent ones of the plurality of second conductive layers in the second direction and extending in the first direction, and provided on the first stacked structure, a third insulating layer provided between the first stacked structure and the second stacked structure, a third conductive layer provided in the first stacked structure, extending in the second direction, connecting the plurality of first conductive layers to the plurality of first insulating layers, and including a first portion and a second portion provided between the first portion and the third insulating layer, a first variable resistance layer provided between each of the plurality of first conductive layers and the plurality of first insulating layers and the third conductive layer in a third direction intersecting with the first direction and the second direction, a fourth conductive layer provided in the second stacked structure, extending in the second direction, connecting the plurality of second conductive layers to the plurality of second insulating layers, and including a third portion and a fourth portion located more away from the third insulating layer in the second direction than the third portion, a length of the third portion in the first direction being larger than a length of the fourth portion in the first direction, a second variable resistance layer provided between each of the plurality of second conductive layers and the plurality of second insulating layers and the fourth conductive layer in the third direction, and a fifth conductive layer provided in the third insulating layer and electrically connecting the third conductive layer to the fourth conductive layer.

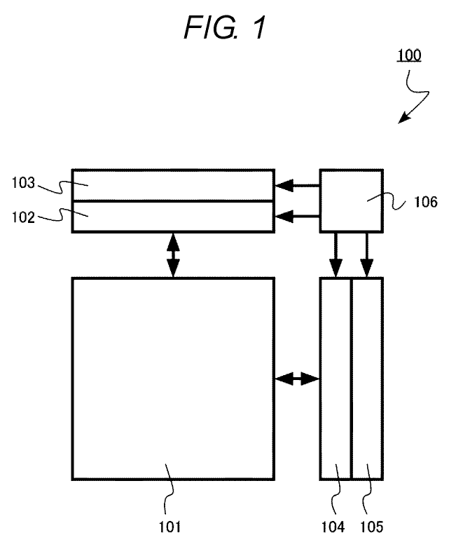

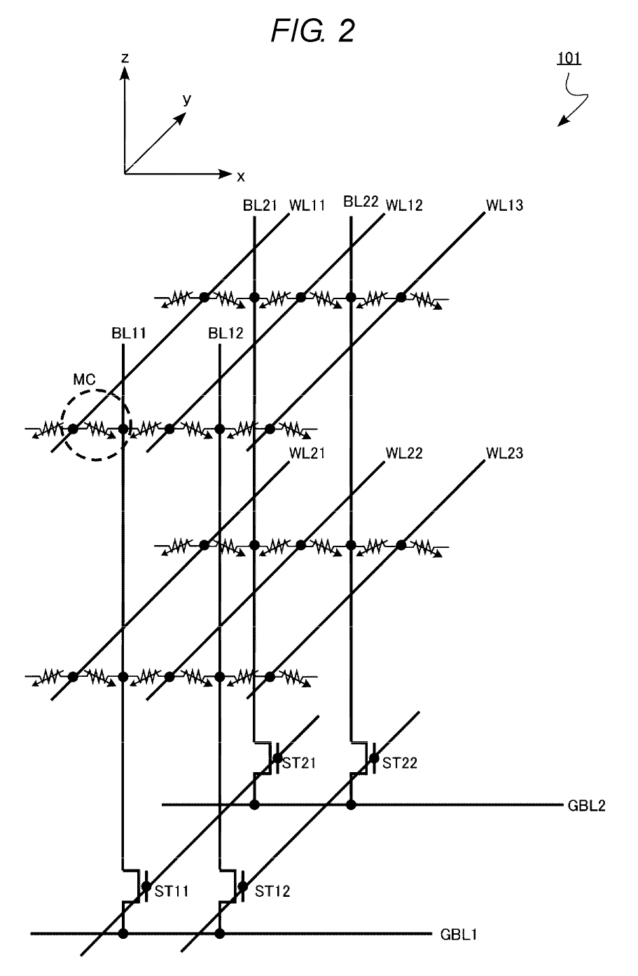

FIG. 1 is a block diagram of a memory device 100 according to some embodiments. FIG. 2 is an equivalent circuit schematic of a memory cell array 101 illustrated in FIG. 1. FIG. 2 schematically illustrates a wiring structure in the memory cell array.

The memory device 100 according to some embodiments is resistive random access memory. The resistive random access memory stores data by utilizing a change of resistance of a variable resistance layer caused by application of a voltage.

Moreover, the memory cell array 101 in some embodiments has a three-dimensional structure in which memory cells are three-dimensionally arranged. The three-dimensional structure of the memory cell array 101 enables improving the degree of integration of the memory device 100.

As illustrated in FIG. 1, the memory device 100 includes a memory cell array 101, a word line driver circuit 102, a row decoder circuit 103, a sense amplifier circuit 104, a column decoder circuit 105, and a control circuit 106.

Moreover, as illustrated in FIG. 2, a plurality of memory cells MC is arranged in three dimensions inside the memory cell array 101. In FIG. 2, a region surrounded by a dashed line corresponds to one memory cell MC.

The memory cell array 101 may include, for example, a plurality of word lines WL (e.g., WL11, WL12, WL13, WL21, WL22, and WL23) and a plurality of bit lines BL (e.g., BL11, BL12, BL21, and BL22). The word line WL may extend in the y-direction. The bit line BL may extend in the z-direction, which intersects at right angles with the x-direction. The memory cell MC may be located at an intersection portion between the word line WL and the bit line BL.

The y-direction is a specific example of a first direction, the z-direction is a specific example of a second direction, and the x-direction, which intersects at right angles with the y-direction and the z-direction, is a specific example of a third direction.

The plurality of word lines WL may be electrically connected to the row decoder circuit 103 (see FIG. 1). The plurality of bit lines BL may be connected to the sense amplifier circuit 104 (see FIG. 1). Select transistors ST (e.g., ST11, ST21, ST12, and ST22) and global bit lines GBL (e.g., GBL1 and GBL2) may be provided between the plurality of bit lines BL and the sense amplifier circuit 104.

The row decoder circuit 103 may have the function of selecting (e.g., may be configured to select) a word line WL according to an input row address signal. The word line driver circuit 102 may have the function of applying (e.g., may be configured to apply) a predetermined voltage to the word line WL selected by the row decoder circuit 103.

The column decoder circuit 105 may have the function of selecting (e.g., may be configured to select) a bit line BL according to an input column address signal. The sense amplifier circuit 104 may have the function of applying (e.g., may be configured to apply) a predetermined voltage to the bit line BL selected by the column decoder circuit 105. Moreover, the sense amplifier circuit 104 may have the function of detecting and amplifying (e.g., may be configured to detect and amplify) a current flowing between the selected word line WL and the selected bit line BL.

The control circuit 106 may have the function of controlling (e.g., maybe configured to control) the word line driver circuit 102, the row decoder circuit 103, the sense amplifier circuit 104, the column decoder circuit 105, and other circuits (not illustrated).

Circuits such as the word line driver circuit 102, the row decoder circuit 103, the sense amplifier circuit 104, the column decoder circuit 105, and the control circuit 106 may be electronic circuits. For example, such circuits may be configured with transistors made from semiconductor layers (not illustrated) and/or wiring layers.

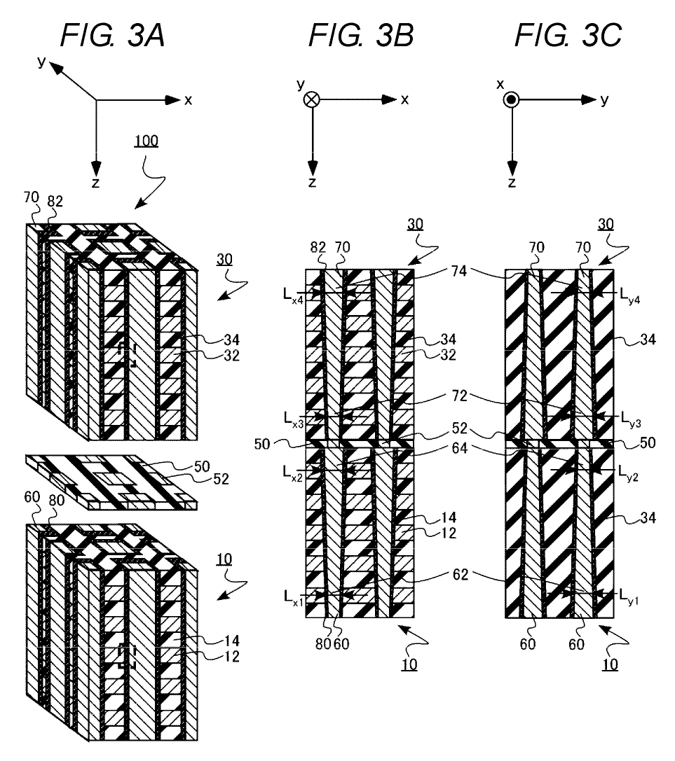

FIG. 3A, FIG. 3B, and FIG. 3C are schematic views of the memory device 100 according to some embodiments.

FIG. 3A is a schematic view of the memory device 100 according to some embodiments. FIG. 3B is a schematic sectional view of the memory device 100 according to some embodiments in an xz cross-section passing through a first conductive layer 12, a second conductive layer 32, a third conductive layer 60, and a fourth conductive layer 70. FIG. 3C is a schematic sectional view of the memory device 100 according to some embodiments in a yz cross-section passing through the third conductive layer 60 and the fourth conductive layer 70. Furthermore, in FIG. 3A, to facilitate visualization of a third insulating layer 50 and a fifth conductive layer 52, which are described below, the third insulating layer 50 and the fifth conductive layer 52 are illustrated in such a way as to be separated from a first stacked structure 10 and a second stacked structure 30, which are described below.

The memory device 100 may include the first stacked structure 10, the second stacked structure 30, and the third insulating layer 50.

The first stacked structure 10 may include a plurality of first conductive layers 12 extending in the y-direction and a plurality of first insulating layers 14 provided between respective adjacent ones of the plurality of first conductive layers 12 and extending in the y-direction. The first conductive layers 12 may be arrayed along the z-direction.

The second stacked structure 30 may be provided above the first stacked structure 10. The second stacked structure 30 may include a plurality of second conductive layers 32 extending in the y-direction and a plurality of second insulating layers 34 provided between respective adjacent ones of the plurality of second conductive layers 32 and extending in the y-direction. The second conductive layers 32 may be arrayed along the z-direction.

The third insulating layer 50 may be provided between the first stacked structure 10 and the second stacked structure 30.

The third conductive layer 60 may be provided in the first stacked structure 10. The third conductive layer 60 may extend in the z-direction and may penetrate (e.g., pass through) the first stacked structure 10. The third conductive layer 60 may connect the plurality of first conductive layers 12 to the plurality of first insulating layers 14.

The fourth conductive layer 70 may be provided in the second stacked structure 30. The fourth conductive layer 70 may extend in the z-direction and penetrate (e.g., pass through) the second stacked structure 30. The fourth conductive layer 70 may connect the plurality of second conductive layers 32 to the plurality of second insulating layers 34.

The fifth conductive layer 52 may be provided in the third insulating layer 50. The fifth conductive layer 52 may electrically connect the third conductive layer 60 to the fourth conductive layer 70.

The first conductive layer 12 and the second conductive layer 32 may be word lines WL. The third conductive layer 60 and the fourth conductive layer 70 may be bit lines BL.

The first conductive layer 12, the second conductive layer 32, the third conductive layer 60, the fourth conductive layer 70, and the fifth conductive layer 52 may be conductive layers. The first conductive layer 12, the second conductive layer 32, the third conductive layer 60, the fourth conductive layer 70, and/or the fifth conductive layer 52 may be, for example, metal layers. The first conductive layer 12, the second conductive layer 32, the third conductive layer 60, the fourth conductive layer 70, and/or the fifth conductive layer 52 may include, for example, tungsten, titanium nitride, or copper. The first conductive layer 12, the second conductive layer 32, the third conductive layer 60, the fourth conductive layer 70, and/or the fifth conductive layer 52 can be formed from another type of metal, a metal semiconductor compound, or an electrically conductive material such as a semiconductor.

The word lines WL may be arranged in the x-direction with a period of, for example, 50 nanometers (nm) or more and 200 nm or less. The thickness in the z-direction of the word line WL may be, for example, 30 nm or less. The bit lines BL maybe arranged in the y-direction with a period of, for example, 50 nm or more and 200 nm or less.

The period of arrangement of the word lines WL in the x-direction, the thickness of the word line WL in the z-direction, the period of arrangement of the bit lines BL in the y-direction, and the thickness of the bit line BL in the z-direction can be measured, for example, by observation with a transmission electron microscope.

The first insulating layer 14 and the second insulating layer 34 may include, for example, an oxide, an oxynitride, or a nitride. The first insulating layer 14 and the second insulating layer 34 may be, for example, oxide silicon (SiO).

It is desirable that the third insulating layer 50 be formed from such a material as to be able to take a higher selection ratio (e.g., etching selectivity) during manufacturing even in comparison with any of the first insulating layer 14, the second insulating layer 34, the third conductive layer 60, or the fourth conductive layer 70. It is desirable that the third insulating layer 50 be, for example, silicon nitride (SiN).

A first variable resistance layer 80 may be provided between the first conductive layers 12 and the third conductive layer 60 and between the first insulating layers 14 and the third conductive layer 60. A second variable resistance layer 82 may be provided between the second conductive layers 32 and the fourth conductive layer 70 and between the second insulating layers 34 and the fourth conductive layer 70.

The first variable resistance layer 80 and the second variable resistance layer 82 may have the function of storing (e.g., may be configured to store) data by a change in resistance state. Moreover, the first variable resistance layer 80 and the second variable resistance layer 82 may allow rewriting of data by receiving application of a voltage or current. The first variable resistance layer 80 and the second variable resistance layer 82 may transition between a high resistance state (e.g., reset state) and a low resistance state (e.g., set state) by receiving application of a voltage or current. For example, the high resistance state is defined as data “0”, and the low resistance state is defined as data “1”.

In FIG. 3A, a region surrounded by a dashed line is one memory cell MC. Each memory cell MC may be provided between the first conductive layer 12 and the third conductive layer 60 and between the second conductive layer 32 and the fourth conductive layer 70. The memory cell MC may store one-bit data of “0” or “1”.

Each of the first variable resistance layer 80 and the second variable resistance layer 82 may be a stacked film of, for example, a chalcogenide including germanium (Ge), antimony (Sb), and tellurium (Te), a binary transition metal oxide such as NiO or TiO₂, a solid electrolyte such as GeS or CuS, a perovskite oxide such as Pr_{0.7}Ca_{0.3}MnO₃ or SrTiO₃, a vacancy-modulated conductive oxide including TiO₂ or WO₃, a semiconductor including silicon or germanium, or a metal oxide including Al, Hf, or Ta.

The length L_{y1} of a first portion 62 of the third conductive layer 60 in the y-direction may be larger than the length L_{y2} of a second portion 64 of the third conductive layer 60 in the y-direction. Moreover, the length Lₓ₁ of the first portion 62 of the third conductive layer 60 in the x-direction may be smaller than the length Lₓ₂ of the second portion 64 of the third conductive layer 60 in the x-direction. Here, the second portion 64 may be provided between the first portion 62 and the second stacked structure 30.

The length L_{y3} of a third portion 72 of the fourth conductive layer 70 in the y-direction may be larger than the length L_{y4} of a fourth portion 74 of the fourth conductive layer 70 in the y-direction. Moreover, the length Lₓ₃ of the third portion 72 of the fourth conductive layer 70 in the x-direction may be smaller than the length Lₓ₄ of the fourth portion 74 of the fourth conductive layer 70 in the x-direction. Here, the fourth portion 74 may be located farther away from the third insulating layer 50 than the third portion 72 in the z-direction. In other words, the third portion 72 may be provided between the fourth portion 74 and the first stacked structure 10.

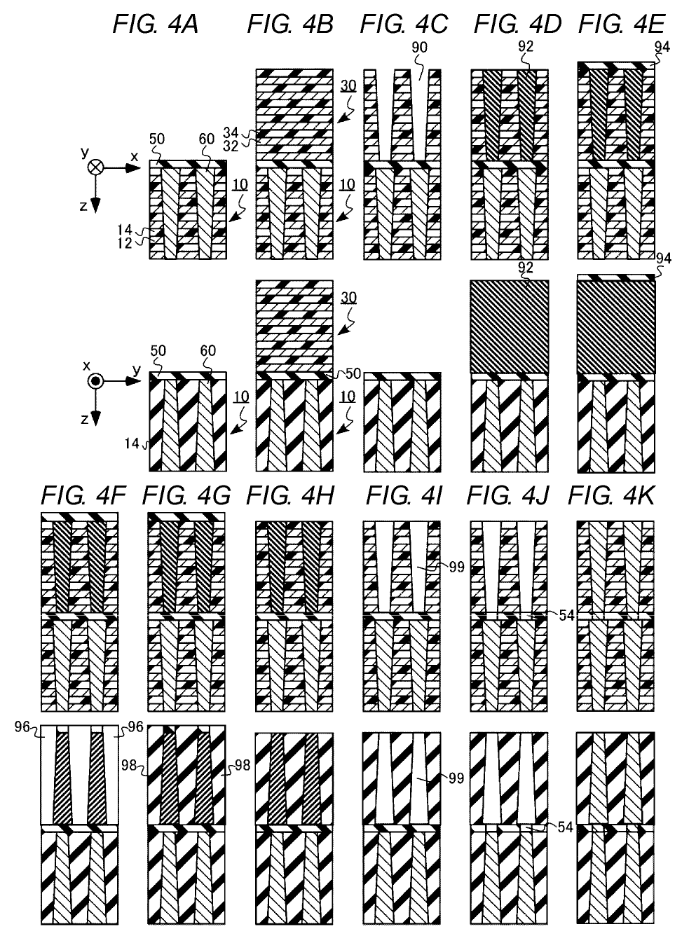

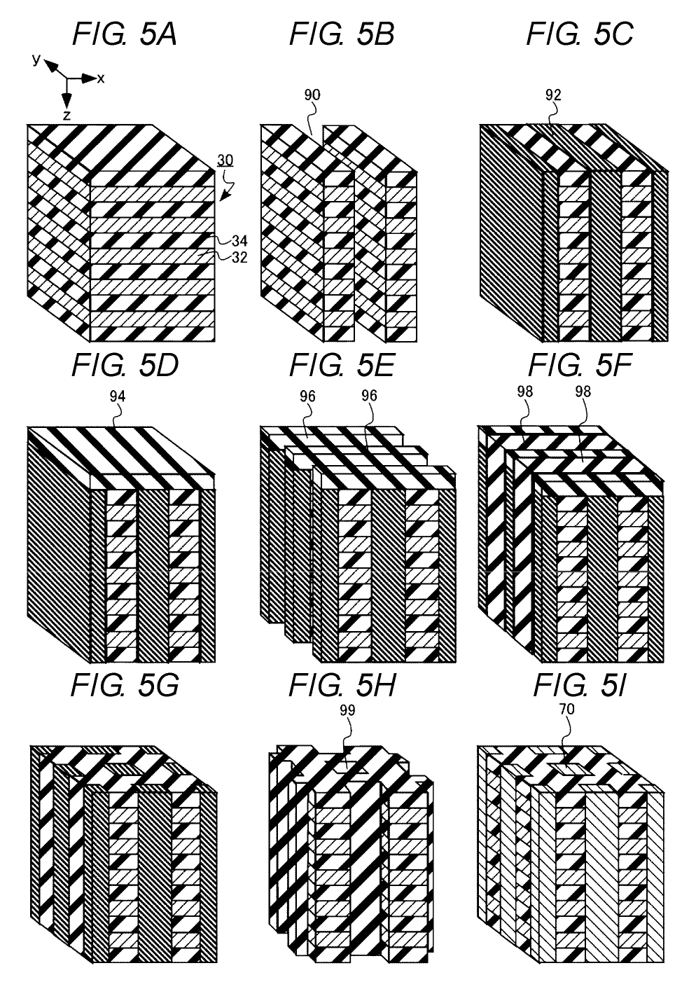

FIG. 4A, FIG. 4B, FIG. 4C, FIG. 4D, FIG. 4E, FIG. 4F, FIG. 4G, FIG. 4H, FIG. 4I, FIG. 4J, and FIG. 4K and FIG. 5A, FIG. 5B, FIG. 5C, FIG. 5D, FIG. 5E, FIG. 5F, FIG. 5G, FIG. 5H, and FIG. 5I are schematic views illustrating a method for manufacturing the memory device 100 according to some embodiments.

In each of FIG. 4A to FIG. 4K, two figures are respectively illustrated at upper and lower portions thereof (hereinafter, referred to as “upper figure” and “lower figure”). In these two figures, the upper figure is a schematic sectional view illustrating a manufacturing process for the memory device 100 illustrated in FIG. 3A, from a plane formed by cutting-through with an xz cross-section passing through the first conductive layer 12, the second conductive layer 32, the third conductive layer 60, and the fourth conductive layer 70. Moreover, in these two figures, the lower figure is a schematic sectional view illustrating a manufacturing process for the memory device 100 illustrated in FIG. 3A, from a plane formed by cutting-through with a yz cross-section passing through the third conductive layer 60 and the fourth conductive layer 70.

FIG. 5A to FIG. 5I are schematic views illustrating portions of a method for manufacturing the second stacked structure 30 in the method for manufacturing the memory device 100 according to some embodiments.

Furthermore, in FIG. 4A to FIG. 4K and FIG. 5A to FIG. 5I, the first variable resistance layer 80 and the second variable resistance layer 82 are omitted from illustration.

The method for manufacturing the memory device 100 according to some embodiments may form a first stacked structure including a plurality of first conductive layers extending in a first direction and a plurality of first insulating layers provided between respective adjacent ones of the plurality of first conductive layers and extending in the first direction. The method may form, in the first stacked structure, grooves extending in a third direction intersecting with a second direction intersecting with the first direction and penetrating (e.g., passing through) the first stacked structure and the first direction, forms sacrificial materials in the grooves. The method may form holes in the first stacked structure, form insulating materials in the holes, remove the sacrificial materials, and form fourth conductive layers at portions with the sacrificial materials removed therefrom.

First, as illustrated in FIG. 4A, the method may form a third insulating layer 50 on the first stacked structure 10.

Next, as illustrated in FIG. 4B and FIG. 5A, the method may form, on the third insulating layer 50, a second stacked structure 30 including a plurality of second conductive layers 32 extending in the x-direction and the y-direction and a plurality of second insulating layers 34 provided between respective adjacent ones of the plurality of second conductive layers 32 and extending in the x-direction and the y-direction.

Next, as illustrated in FIG. 4C and FIG. 5B, the method may form grooves 90 extending in the y-direction in the second stacked structure 30 with use of, for example, photolithography and reactive ion etching (RIE).

Next, as illustrated in FIG. 4D and FIG. 5C, the method may form a sacrificial material 92 in each of the grooves 90, and then may planarize the upper surface of the second stacked structure 30 with use of etchback.

It is desirable that the sacrificial material 92 include a material capable of being easily formed and likely to be selectively removed with respect to the second conductive layer 32 and the second insulating layer 34. It is desirable that the sacrificial material 92 include, for example, polysilicon or amorphous silicon.

Next, as illustrated in FIG. 4E and FIG. 5D, the method may form a hard mask 94 including, for example, silicon nitride (SiN) on the second stacked structure 30.

Next, as illustrated in FIG. 4F and FIG. 5E, the method may form first holes (e.g., holes) 96 extending in the z-direction in the second stacked structure 30 and the hard mask 94 with use of, for example, photolithography and RIE.

Next, as illustrated in FIG. 4G and FIG. 5F, the method may form an insulating material 98 including, for example, silicon oxide in each of the first holes 96, and then may planarize the upper surface of each of the hard mask 94 and the insulating material 98 with use of, for example, chemical metal polishing (CMP).

Next, as illustrated in FIG. 4H and FIG. 5G, the method may remove the hard mask 94 and a part of the insulating material 98 with use of, for example, etchback, and then may planarizes the upper surface of the second stacked structure 30.

Next, as illustrated in FIG. 4I and FIG. 5H, the method may remove the sacrificial materials 92 with use of, for example, wet etching using an alkaline solution. With this, portions 99 with sacrificial materials removed therefrom may be formed.

Next, as illustrated in FIG. 4J, the method may remove a part of the third insulating layer 50 provided under the groove 90 with use of, for example, RIE to form second holes 54, thus exposing the upper surface of the third conductive layer 60.

Next, after depositing a second variable resistance layer (not illustrated) on the inside surface of the portion 99 with a sacrificial material removed therefrom, as illustrated in FIG. 4K and FIG. 5I, the method may form a fourth conductive layer 70 in the second hole 54 and in the portion 99 with a sacrificial material removed therefrom and with the second variable resistance layer deposited on the inside surface thereof, thus attaining the memory device 100 according to some embodiments.

Next, a functional effect of the memory device 100 according to some embodiments is described.

If, to attain a high-density integration of a memory device, the number of layers of the second conductive layers 32 and the number of layers of the second insulating layers 34, which form the second stacked structure 30, are made larger, the length of the fourth conductive layer 70, which penetrates (e.g., passes through) the second conductive layers 32 and the second insulating layers 34, in the z-direction becomes larger.

However, it is difficult to form a fourth conductive layer 70 the lengths of which in the x-direction and the y-direction are uniform. Generally, in the case of forming a groove with use of, for example, RIE to form the fourth conductive layer 70, the width of the upper groove portion is likely to become larger than the width of the lower groove portion. Since the fourth conductive layer 70 is formed in the groove, as a result, the lengths of an upper portion of the fourth conductive layer 70 in the x-direction and the y-direction are likely to become larger than the lengths of a lower portion of the fourth conductive layer 70 in the x-direction and the y-direction.

Since it is difficult to form the fourth conductive layer 70 in a uniform manner, in current practices, a plurality of stacked structures, such as the first stacked structure 10 and the second stacked structure 30, is provided, and the third conductive layer 60 and the fourth conductive layer 70 are electrically interconnected by the fifth conductive layer 52 provided in the third insulating layer 50. However, in such a case, an issue arises in that the contact resistance between the fifth conductive layer 52 and the fourth conductive layer 70 increases.

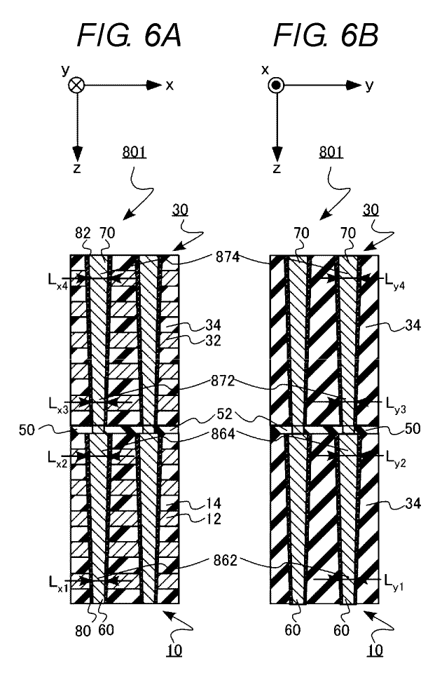

FIG. 6A and FIG. 6B are schematic views of a memory cell array 801 of a memory device 800 serving as a comparative configuration.

In the memory cell array 801, the length L_{y1} of a first portion 862 in the y-direction is smaller than the length L_{y2} of a second portion 864 in the y-direction. Moreover, the length L_{y3} of a third portion 872 in the y-direction is smaller than the length L_{y4} of a fourth portion 874 in the y-direction.

Moreover, the length Lₓ₁ of the first portion 862 in the x-direction is smaller than the length Lₓ₂ of the second portion 864 in the x-direction. Moreover, the length Lₓ₃ of the third portion 872 in the x-direction is smaller than the length Lₓ₄ of the fourth portion 874 in the x-direction.

Therefore, an area at which the fourth conductive layer 70 and the fifth conductive layer 52 contact each other would become small. As the number of layers of the second conductive layers 32 and the number of layers of the second insulating layers 34 become larger to attain a high-density integration of the memory cell MC, such a tendency becomes more conspicuous. For example, as compared with the lengths in the x-direction and the y-direction of the fourth conductive layer 70 at the uppermost layer portion of the second stacked structure 30, the lengths in the x-direction and the y-direction of the fourth conductive layer 70 at the lowermost layer portion of the second stacked structure 30 would become as smaller as 70%. Therefore, as compared with the area in the xy plane of the fourth conductive layer 70 at the uppermost layer portion of the second stacked structure 30, the area in the xy plane of the fourth conductive layer 70 at the lowermost layer portion of the second stacked structure 30 would become as smaller as 49%. Therefore, an issue arises in that the contact resistance of wirings used to allow a write current or read current for the memory cell to flow becomes large.

In the memory device 100 according to some embodiments, the length L_{y3} of the third portion 72 in the y-direction may be larger than the length L_{y4} of the fourth portion 74 in the y-direction (see FIG. 3C). Therefore, the contact resistance of wirings interconnecting the third conductive layer 60 and the fourth conductive layer 70 can be reduced.

Moreover, in the memory device 100 according to some embodiments the length Lₓ₃ of the third portion 72 in the x-direction may be smaller than the length Lₓ₄ of the fourth portion 74 in the x-direction (see FIG. 3B). The fourth conductive layer 70 in which the length Lₓ₃ is smaller than the length Lₓ₄ can be easily manufactured. Furthermore, the area in the xy plane of the fourth conductive layer 70 at the uppermost layer portion of the second stacked structure 30 and the area in the xy plane of the fourth conductive layer 70 at the lowermost layer portion of the second stacked structure 30 may become almost the same. Therefore, providing a memory device 100 which is capable of being easily manufactured and is reduced in contact resistance is enabled.

Moreover, the length L_{y1} of the first portion 62 in the y-direction may be larger than the length L_{y2} of the second portion 64 in the y-direction (see FIG. 3C), and the length Lₓ₁ of the first portion 62 in the x-direction may be smaller than the length Lₓ₂ of the second portion 64 in the x-direction (see FIG. 3B).

The select transistors ST and the global bit lines GBL may be provided below the first stacked structure 10. Accordingly, providing a memory device 100 which is reduced in contact resistance with respect to the select transistors ST and the global bit lines GBL is enabled.

The method for manufacturing the memory device 100 according to some embodiments may form grooves 90 extending in the y-direction (see FIG. 4C and FIG. 5B), forms sacrificial materials 92 in the grooves 90 (see FIG. 4D and FIG. 5C), forms first holes 96 (see FIG. 4F and FIG. 5E), forms insulating materials 98 in the first holes 96 (see FIG. 4G and FIG. 5F), removes the sacrificial materials 92 (see FIG. 4I and FIG. 5H), and forms fourth conductive layers 70 at portions with the sacrificial materials removed therefrom (see FIG. 4K and FIG. 5I).

The shape of each of the groove 90 and the first hole 96 maybe a general shape in which the length of the upper portion is large and the length of the lower portion is small. The method for manufacturing according to some embodiments may remove the sacrificial materials 92 formed in the grooves 90 and, after that, may form the fourth conductive layers 70. Therefore, manufacturing the fourth conductive layer 70 in which the length of the upper portion is small and the length of the lower portion is large, as in the memory device 100 according to some embodiments, contrary to a general shape of the fourth conductive layer 70, is enabled.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A memory device comprising:
a first stacked structure including a plurality of first conductive layers extending in a first direction and arrayed along a second direction intersecting with the first direction and a plurality of first insulating layers extending in the first direction and provided between respective adjacent ones of the plurality of first conductive layers in the second direction;
a second stacked structure including a plurality of second conductive layers extending in the first direction and arrayed along the second direction and a plurality of second insulating layers provided between respective adjacent ones of the plurality of second conductive layers in the second direction and extending in the first direction, and provided on the first stacked structure;
a third insulating layer provided between the first stacked structure and the second stacked structure;
a third conductive layer provided in the first stacked structure, extending in the second direction, connecting the plurality of first conductive layers to the plurality of first insulating layers, and including a first portion and a second portion provided between the first portion and the third insulating layer;
a first variable resistance layer provided between each of the plurality of first conductive layers and the plurality of first insulating layers and the third conductive layer in a third direction intersecting with the first direction and the second direction;
a fourth conductive layer provided in the second stacked structure, extending in the second direction, connecting the plurality of second conductive layers to the plurality of second insulating layers, and including a third portion and a fourth portion located farther away from the third insulating layer in the second direction than the third portion, a length of the third portion in the first direction being larger than a length of the fourth portion in the first direction;
a second variable resistance layer provided between each of the plurality of second conductive layers and the plurality of second insulating layers and the fourth conductive layer in the third direction; and
a fifth conductive layer provided in the third insulating layer and electrically connecting the third conductive layer to the fourth conductive layer.

2. The memory device according to claim 1, wherein a length of the third portion in the third direction is smaller than a length of the fourth portion in the third direction.

3. The memory device according to claim 1, wherein a length of the first portion in the first direction is larger than a length of the second portion in the first direction.

4. The memory device according to claim 1, wherein a length of the first portion in the third direction is smaller than a length of the second portion in the third direction.

5. A method for manufacturing a memory device, the method comprising:
forming a first stacked structure including a plurality of first conductive layers extending in a first direction and a plurality of first insulating layers provided between respective adjacent ones of the plurality of first conductive layers and extending in the first direction;
forming, in the first stacked structure, grooves extending in a third direction intersecting with a second direction intersecting with the first direction and penetrating through the first stacked structure and the first direction;
forming sacrificial materials in the grooves;
forming holes in the first stacked structure;
forming insulating materials in the holes;
removing the sacrificial materials; and
forming third conductive layers at portions with the sacrificial materials removed therefrom.

6. The method according to claim 5, further comprising:
forming a third insulating layer on the first stacked structure,
wherein the third conductive layers include a first portion and a second portion provided between the first portion and the third insulating layer.

7. The method according to claim 6, wherein a length of the first portion in the first direction is larger than a length of the second portion in the first direction.

8. The method according to claim 6, wherein a length of the first portion in the third direction is smaller than a length of the second portion in the third direction.

9. The method according to claim 5, further comprising:
forming, on the first stacked structure, a second stacked structure including a plurality of third conductive layers extending in the first direction and a plurality of second insulating layers provided between respective adjacent ones of the plurality of third conductive layers and extending in the first direction;
forming, in the second stacked structure, second grooves extending in the third direction and penetrating the second stacked structure and the first direction;
forming second sacrificial materials in the second grooves;
forming second holes in the second stacked structure;
forming second insulating materials in the second holes;
removing the second sacrificial materials; and
forming fourth conductive layers at portions with the second sacrificial materials removed therefrom.

10. The method according to claim 9,
wherein the fourth conductive layers include a third portion and a fourth portion located farther away from the third insulating layer in the second direction than the third portion, a length of the third portion in the first direction being larger than a length of the fourth portion in the first direction.

11. The method according to claim 10, wherein a length of the third portion in the third direction is smaller than a length of the fourth portion in the third direction.
